(19) United States
(12) Patent Application Publication
(10) Pub. No.: US 2021/0035944 A1
(43) Pub. Date: Feb. 4, 2021

(54) CHIP PACKAGE FABRICATION KIT AND CHIP PACKAGE FABRICATING METHOD THEREOF

(71) Applicant: TIEN CHIEN CHENG, HSIN CHU CITY (TW)

(72) Inventor: TIEN CHIEN CHENG, HSIN CHU CITY (TW)

(21) Appl. No.: 16/945,171

(22) Filed: Jul. 31, 2020

Related U.S. Application Data
(60) Provisional application No. 62/881,928, filed on Aug. 1, 2019.

(51) Int. Cl. H01L 23/00; H01L 23/32; H01L 23/498; H01L 23/40

(52) U.S. Cl. CPC H01L 24/81; H01L 23/32; H01L 24/16; H01L 23/49816; H01L 2023/4087; H01L 2224/16225; H01L 2224/81007; H01L 2224/81203; H01L 2924/3511; H01L 23/4006

(57) ABSTRACT

A chip package fabricating kit includes a metal cover, at least one screw, and at least one screw cap. The metal cover includes a cap portion and at least one leg. The cap portion substantially presses against the BGA package. The leg substantially presses a PCB board that loads the BGA package. The leg forms a concave space with the metal cover for substantially encompassing the BGA package. Each the screw screws through a corresponding leg from top to bottom. Each the screw screws the PCB board at a first side. The screw cap respectively corresponds to the screw and one leg. The screw cap caps and fixes a tail of its corresponding screw for affixing the PCB board. A height of the concave space is dynamically adjusted by adjusting a degree that the screw screws with the screw cap. Such that the concave space substantially clamps the BGA package.

### CROSS REFERENCE TO RELATED APPLICATION

This application claims the benefit of U.S. Provisional Application No. 62/881,928 filed on Aug. 1, 2019 and entitled “Method of Fabricating Chips”, the contents of which are incorporated herein by reference.

### FIELD OF THE INVENTION

The present invention relates to a chip package fabricating kit and a chip package fabricating method of the chip package fabricating kit, and more particularly, to a chip package fabricating kit capable of fabricating large-area ball grid array (BGA) package and a chip package fabricating method thereof.

### DESCRIPTION OF THE PRIOR ART

A conventional BGA package faces its limitation in chip area. It is because a chip carried by the conventional BGA package inevitably and significantly deforms while being baked. Such deformation directly reduces a yield rate of fabricating the conventional BGA package.

### SUMMARY OF THE INVENTION

The present disclosure aims at disclosing a chip package fabricating kit and a chip package fabricating method thereof.

The disclosed chip package fabricating kit includes a metal cover, at least one screw, and at least one screw cap. The metal cover includes a cap portion and at least one leg. The cap portion substantially presses against at least one BGA package. The at least one leg substantially presses a printed circuit board (PCB) board that loads the BGA package. Also, the at least one leg forms a concave space with the metal cover for substantially encompassing the at least one BGA package. Each of the at least one screw screws through a corresponding leg of the metal cover from top to bottom. In addition, each the at least one screw screws the PCB board at a first side of said PCB board. The at least one screw cap respectively corresponds to one of the at least one screw and one of the at least one leg of the metal cover. Moreover, the at least one screw cap caps and fixes a tail of its corresponding screw for affixing the PCB board. A height of the concave space is dynamically adjusted by adjusting a degree that the at least one screw screws with the at least one screw cap. Such that the concave space substantially clamps the BGA package.

In one example, the chip package fabricating kit also includes at least one buffer pad that is respectively corresponding to the at least one leg of the metal cover. Besides, the at least one buffer pad is disposed between the at least one leg and the PCB board.

In one example, the at least one buffer pad includes metal or organic materials.

In one example, the chip package fabricating kit also includes a metal plate that is disposed between the at least one screw cap and the PCB board at a second side. And the second side of the PCB board is opposite to the first side of said PCB board.

In one example, the metal plate substantially contacts with the PCB board at the second side of said PCB board. And the metal plate clamps the PCB board onto the BGA package with the aid of the metal cover.

In one example, the metal cover includes stainless steel, alloy or other heat-resisting and stiff materials.

In one example, the at least one leg of the metal cover forms an enclosing edge that surrounds the BGA package.

In one example, the BGA package includes a chip, a metal frame and a substrate. The metal frame substantially surrounds the chip. And the substrate loads both the chip and the metal frame.

In one example, the BGA package also includes a plurality of solder balls that are disposed between the substrate and the PCB board. Besides, the BGA package sticks the substrate to the PCB board upon soldering.

In one example, the BGA package also includes a plurality of solder pins that are disposed between the substrate and the chip. In addition, the plurality of solder pins attach the chip to the substrate by soldering.

In one example, the BGA package also includes an adhesive that is disposed between the metal frame and the substrate. And the adhesive attaches the metal frame to the substrate.

In the disclosed chip package fabricating method, the at least one BGA package is disposed onto a PCB board. The metal cover is disposed for substantially contacting with a chip and a metal frame of the BGA package. And the metal frame surrounds the chip to encompass the BGA package. The metal cover is then pressed against the BGA package. Such that a substrate of the BGA package substantially contacts with the PCB board. The substrate substantially loads the chip and the metal frame. The at least one screw screws respectively through each of at least one leg of the metal cover from top to bottom and through the PCB board. The at least one screw cap respectively corresponds with the at least one screw. Also, the at least one screw is capped to a tail of each the at least one screw for affixing the BGA package onto the PCB board. Last, the BGA package is baked.

In one example, a thermal interface material (TIM) layer is sputtered onto the BGA package.

In one example, a metal plate is disposed between the PCB board and the at least one screw cap.

In one example, the at least one screw cap is capped to the tail of each the at least one screw for clamping PCB board onto the BGA package.

In one example, a degree that the at least one screw screws with the at least one screw cap is dynamically adjusted. Such that a concave space of the metal cover substantially clamps the BGA package.

In one example, at least one buffer pad respectively corresponds to the at least one leg of the metal cover. And the at least one buffer pad is disposed between the at least one leg of the metal cover and the PCB board.

In one example, a plurality of soldering pins is disposed between the chip and the substrate of the BGA package. And the plurality of soldering pins are soldered for affixing the chip onto the substrate.

In one example, a plurality of soldering balls are disposed between the substrate of the BGA package and the PCB board. And the plurality of soldering balls are soldered for affixing the substrate onto the PCB board.

In one example, an adhesive between the metal frame and the substrate is disposed for firmly attaching the metal frame to the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic top view of a ring-type BGA according to a first example.

FIG. 2 illustrates a schematic lateral view of the ring-type BGA shown in FIG. 1.

FIG. 3 illustrates a lid-type BGA package according to a second example.

FIG. 4 and FIG. 5 illustrate schematic diagrams of a deformed large-scale chip of an BGA package while the BGA package is baked.

FIG. 6 illustrates a schematic lateral view of a chip package fabricating kit according to a first example of the present disclosure.

FIG. 7 illustrates a schematic lateral view of another example of the chip package fabricating kit that further includes a metal plate.

FIG. 8 illustrates a chip package fabricating method according to one example.

### DETAILED DESCRIPTION

For substantially neutralizing the deformation defect of chips while a BGA package is baked, the present disclosure discloses a chip package fabricating kit and a chip package fabricating method that said chip package fabricating kit uses. Specifically, the chip package fabricating kit and its method effectively suppresses the chip's deformation during the baking process.

A ball grid array (BGA) package is a type of surface-mount packaging used for integrated circuits. Also, a BGA package can be used to permanently mount electronic devices, such as microprocessors. Moreover, a BGA provides more interconnection pins than those a dual in-line package or a flat package does.

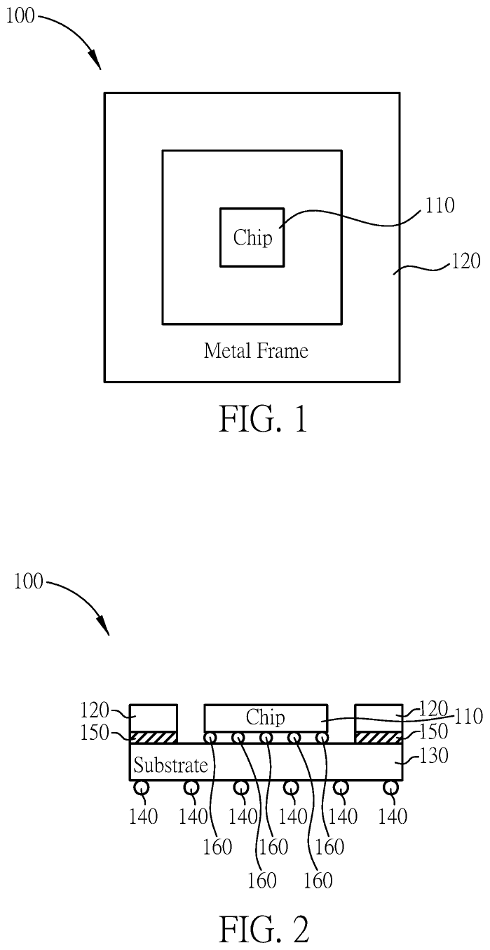

FIG. 1 illustrates a schematic top view of a ring-type BGA 100 according to a first example. And FIG. 2 illustrates a schematic lateral view of the ring-type BGA 100 shown in FIG. 1.

The ring-type BGA 100 includes a chip 110 and a metal frame 120 that surrounds the chip 110. Also, the ring-type BGA 100 includes a substrate 130, multiple solder balls 140, adhesives 150, and multiple solder pins 160.

The substrate 130 loads both the chip 110 and the metal frame 120.

The solder balls 140 sticks the substrate 130 to an underlying PCB board that sits under the solder balls 140 via soldering. Specifically, while the solder balls 140 are welded to the underlying PCB board, the substrate 130 tightly attaches to the PCB board.

The adhesives 150 attaches the metal frame 120 to the substrate 130, for example, by gluing the metal frame 120 to the substrate 130.

The solder pins 160 attaches the chip 110 to the substrate 130 for fixing the chip 110. Specifically, the solder pins 160 can be welded such that the chip 110 tightly attaches to the substrate 130.

While fabricating the ring-type BGA 100, the ring-type BGA 100 is put on a tape carrier package for at least baking. While the ring-type BGA 100 is baked, the chip 110 does not deform significantly since the solder pins 160 tightly attaches the chip 110 to the substrate 130, for example, via welding.

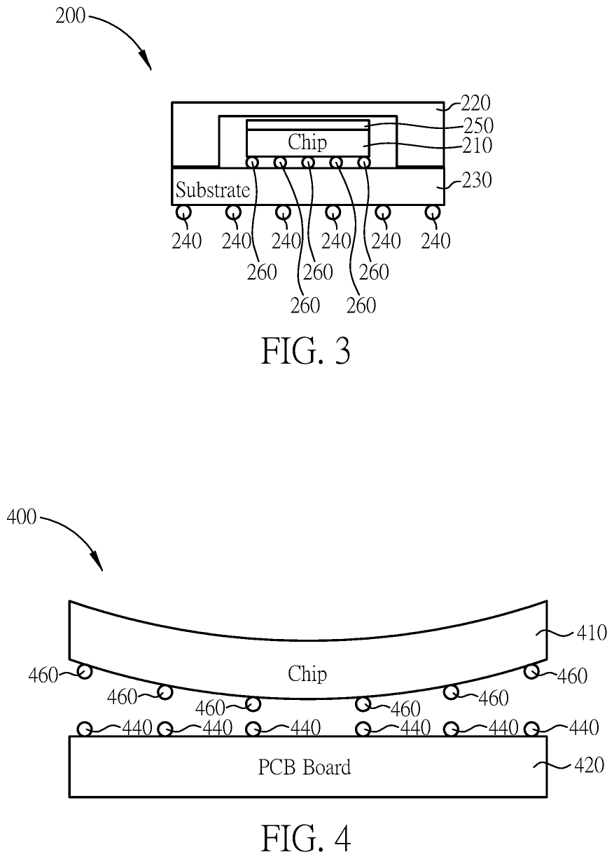

FIG. 3 also illustrates a lid-type BGA package 200 according to a second example. The lid-type BGA package 200 includes a chip 210 and a thin metal lid 220 that substantially presses against the chip 210 at its top side to attach to an underlying substrate 230.

In addition, the lid-type BGA package 200 includes the substrate 230, multiple solder balls 240, a thermal interface material (TIM) layer 250 and multiple solder pins 260.

Similarly, the thin metal lid 220 substantially surrounds the chip 210. However, the thin metal lid 220 also substantially covers the chip 210.

The substrate 230 loads both the chip 210 and the metal frame 220.

The solder balls 240 sticks the substrate 230 to an underlying PCB board that sits under the solder balls 240 via soldering. Specifically, while the solder balls 240 are welded to the underlying PCB board, the substrate 230 tightly attaches to the PCB board.

The TIM layer 250 forms a heat sink for the chip 210. Also, the thin metal lid 220 slightly resists the chip 210's deformation force while the lid-type BGA package 200 is baked.

The solder pins 260 attaches the chip 210 to the substrate 230 for fixing the chip 210. Specifically, the solder pins 260 can be welded such that the chip 210 tightly attaches to the substrate 230.

Although both the BGA packages 100 and 200 can prevent respective chips 110 and 210 from significantly deforming while being baked, however, both the chips 110 and 210 cannot have large areas. Specifically, the chip 110 or 210's large area may introduce a large shear vertical force that is orthogonal to the substrate 130 or 230. And such shear force outweighs the underlying solder pins 160 or 260's resistance to stop the chip 110 or 210's deformation force.

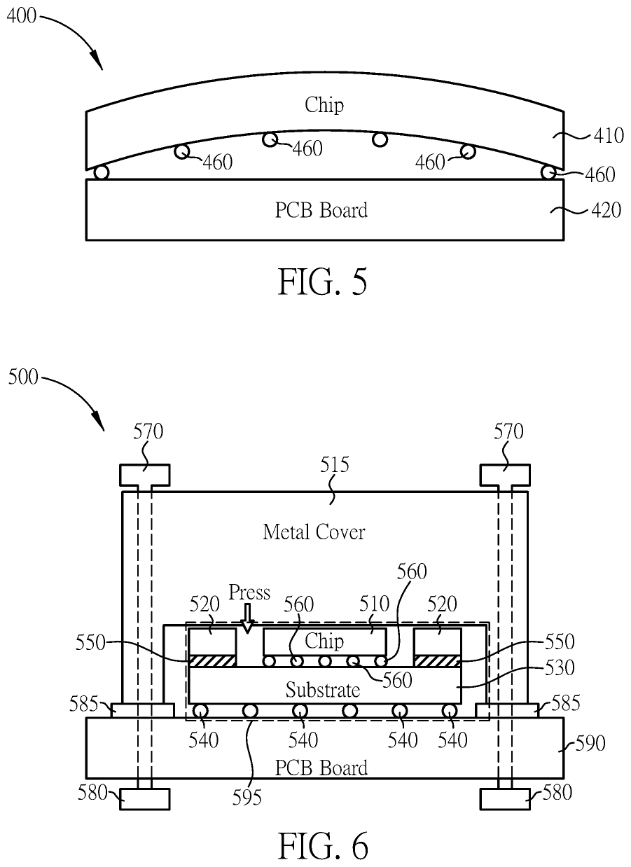

FIG. 4 and FIG. 5 illustrate schematic diagrams of a deformed large-scale chip of an BGA package 400 while the BGA package 400 is baked. As illustrated, the BGA package 400 includes at least a chip 410, a PCB board 420, multiple solder balls 460 that are attached to the chip 410, and multiple solder balls 440 that are attached to the PCB board 420.

The chip 400's deformation renders itself to detach from the underlying PCB board 420's pins (e.g., solder balls 440). As a result, the BGA package 400 may be sabotaged upon completion. For preventing the chip 410 from its deformation, the BGA package 400's area has to be limited. In some examples, the BGA package 400's upper-bound area is at most 70×70 mm2 for ensuring the chip 410 from its deformation.

The present disclosure discloses a method of fabricating chips via BGA packages. With the aid of the disclosed method, the abovementioned limitation in chip area can be substantially overcome.

FIG. 6 illustrates a schematic lateral view of a chip package fabricating kit 500 according to a first example of the present disclosure. The chip package fabricating kit 500 aims at fabricating a BGA package 595 by baking said BGA package 595.

In some examples, the BGA package 595 includes a chip 510, a metal frame 520, a substrate 530, multiple solder balls 540, at least one adhesive 550, and multiple solder pins 560. And the chip package fabricating kit 500 affixes the BGA package 595 onto a PCB board 590. That is, the chip package fabricating kit 500's final product includes a combination of the BGA package 595 and the PCB board 590.

The metal frame 520 substantially surrounds the chip 510.

The substrate 530 loads both the chip 510 and the metal frame 520.

The solder balls 540 sticks the substrate 530 to the underlying PCB board 590 that sits under the solder balls 540 via soldering. Specifically, while the solder balls 540 are welded (i.e., soldered) to the underlying PCB board 590, the substrate 230 tightly attaches to the PCB board 590.

The adhesive 550 attaches the metal frame 520 to the substrate 530, for example, by gluing the metal frame 520 to the substrate 530.

The solder pins 560 attaches the chip 510 to the substrate 530 for fixing the chip 510. Specifically, the solder pins 560 can be welded (i.e., soldered) such that the chip 510 tightly attaches to the substrate 530.

The chip package fabricating kit 500 includes at least a metal cover 515, multiple screws 570 and multiple screw caps 580. Also, the chip package fabricating kit 500 may optionally include multiple buffer pads 585.

The metal cover 515 has at least one leg that substantially contacts with the PCB board 590 at multiple contact points. In addition, the metal cover 515 has a cap portion for substantially covering the BGA package 595. Such that the metal cover 515 can exert a stress force towards the PCB board 590 via the multiple contact points. Also, the metal cover 515's cap portion and at least one leg form a concave space that is used for substantially encompass the BGA package 595. In some examples, the metal cover 515 can be ring-shaped such that its at least one leg becomes an enclosing edge for encompassing the BGA package 595 in a surrounding manner.

The metal cover 515 is designed to be significantly larger than the metal lid 210 in at least height, width (i.e., area) and thickness. Also, the metal cover 515's cap portion substantially presses against the chip 510, the metal frame 520 via its inner wall within its concave space. In this way, while the chip package fabricating kit 500 is baked, the metal cover 515 can firmly fix the chip 510 to the substrate 530 and effectively prevent said chip 510 from deforming. Also, the chip 510's area is significantly larger than the chips 110 and 210's. In some examples, the chip 510's area is 100×100 mm2 or larger. In some examples, the metal cover 515 is made of stainless steel, alloy or other heat-resisting and stiff materials for resisting thermal effects.

For additionally ensuring the metal cover 515 to tightly press against the chip 510, the chip package fabricating kit 500 uses multiple screws 570 and multiple screw caps 580. It is noted that each the screw 570 corresponds to a unique screw cap 580 to form a pair. Also, each the metal cover 515's leg corresponds to a unique pair of the screw 570 and the screw cap 580. Specifically, the screws 570 screw through each of the metal cover 515's legs from top to bottom and even the PCB board 590 at a first side of the PCB board 590 (via appropriate design on said PCB board 590). Also, the screw caps 580 caps and fixes the screws 570's tail at a second side of the PCB board 590 that is opposite to the first side of the PCB board 590. It is noted that a relative distance from the metal cover 515's cap portion to a top side of the PCB board 590 (i.e., the metal cover 515's concave space's height) can be dynamically adjusted by a degree of screwing the screws 570 onto the screw cap 580 (e.g. a relative distance between each the screw 570's head and the screw cap 580).

The buffer pads 585 are optionally disposed between the metal cover 515's legs and the PCB board 590 for at least partially absorbing a stress force between the metal cover 515's legs and the PCB board 590. Such that the PCB board 590 will not be broken apart by the stress force between the metal cover 515's legs and the PCB board 590. In some examples, the buffer pads 585 are made of metal or organic materials for resisting a high stress force between the metal cover 515's legs and the PCB board 590.

In summary, the chip package fabricating kit 500 uses two stress forces to affix the BGA package 595 onto the PCB board 590 while baking the BGA package 595. Such that the chip 510 can be substantially prevented from its deformation. Specifically, the metal cover 515's cap portion provides a first stress force that substantially presses against the chip 510 and the metal frame 520. Also, the metal cover 515's legs provides a second stress force, which is located at the contact surface between the metal cover 515 and the PCB board 590. With the aid of both the screws 570 and the screw caps 580, both the first and second stress forces can better affix the chip 510, the metal layer 520 and the substrate 530 onto the PCB board 590.

In some examples, the chip package fabricating kit 500 simultaneously dispose multiple BGA packages 595 onto the PCB board 590. With the aid of the metal cover 515's large area that covers all those BGA packages 595 above the PCB board 590, the number of disposed BGA packages 595 on the PCB board 590 can be adjusted. In this way, the chip package fabricating kit 500 does not only fit for a single large-area BGA chip packages 595 that carries a single large-area chip 510, but it also encompasses multiple large-area BGA chip packages 595. And that significantly facilitates more dynamic and various chip designs on the PCB board 590.

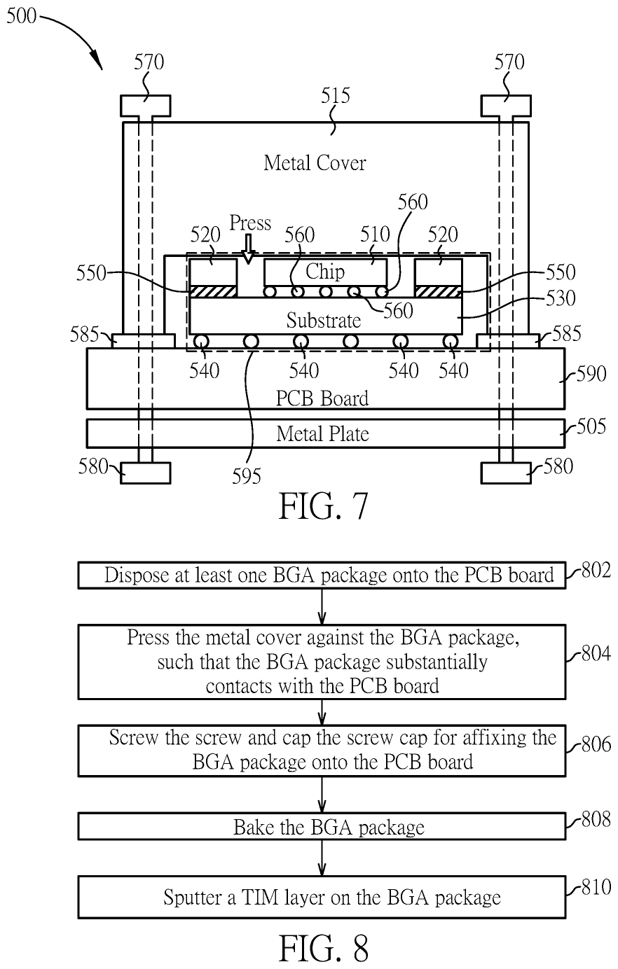

FIG. 7 illustrates a schematic lateral view of another example of the chip package fabricating kit 500 that further includes a metal plate 505. Specifically, the metal plate 505 is disposed between the screw caps 580 and the PCB board 590, i.e., at a backside of the PCB board 590. Also, the metal plate 505 substantially contacts the PCB board 590 at its backside. Such that the metal cover 515 and the metal plate 505 substantially clamp the PCB board 590 onto the BGA package 595. In this way, the PCB board 590 can have better support to resist both the first and second stress forces from the metal cover 515.

It is noted that while the BGA package 595 is baked, the solder pins 560 are welded between the chip 510 and the substrate 530. Such that the chip 510 sticks to the substrate 530 in a tighter manner and enables its operations (e.g., electronic movements) with the substrate 530. Similarly, when the BGA package 595 is baked, the solder balls 540 between the substrate 530 and the PCB board 590 are also welded. Therefore, the PCB board 590 enables its operations (e.g., electronic movements) with the substrate 530 and even the chip 510.

Last, after the BGA package 595 is baked, the metal cover 515, the screws 570, the screw caps 580 are removed. Then a TIM layer is additionally sputtered onto the final product for forming required heat sinks above the chip 510.

How the chip package 500 fabricates the BGA package 590 is described as a chip package fabricating method as shown in FIG. 8 that includes the following steps; Step 802: Dispose at least one BGA package 595 onto the PCB board 590.

Step 804: Press the metal cover 515 against the BGA package 595, such that the BGA package 595 substantially contacts with the PCB board 590. It is noted that the press force on the metal cover can be provided via any designed mechanical mechanism.

Step 806: Screw the screw 570 and cap the screw cap 580 for affixing the BGA package 595 onto the PCB board 590.

Step 808: Bake the BGA package 595.

Step 810: Sputter a TIM layer on the BGA package 595.

It is noted that methods formed by incorporating limitations disclosed in the present disclosure still form embodiments of the present invention.

Those skilled in the art will readily observe that numerous modifications and alterations of the device and method may be made while retaining the teachings of the invention. Accordingly, the above disclosure should be construed as limited only by the metes and bounds of the appended claims.

1. A chip package fabricating kit, comprising:
a metal cover, comprising:
a cap portion, configured to substantially press against at least one ball grid array (BGA) package; and
at least one leg, configured to substantially press a printed circuit board (PCB) board that loads the BGA package, and configured to form a concave space with the metal cover for substantially encompassing the at least one BGA package;
at least one screw, each of which is configured to screw through a corresponding leg of the metal cover from top to bottom and to screw the PCB board at a first side of said PCB board; and
at least one screw cap respectively corresponding to one of the at least one screw and one of the at least one leg of the metal cover, configured to cap and fix a tail of its corresponding screw for affixing the PCB board;
wherein a height of the concave space is dynamically adjusted by adjusting a degree that the at least one screw screws with the at least one screw cap, such that the concave space substantially clamps the BGA package.

2. The chip package fabricating kit of claim 1, further comprising:
at least one buffer pad respectively corresponding to the at least one leg of the metal cover, disposed between the at least one leg and the PCB board.

3. The chip package fabricating kit of claim 2, wherein the at least one buffer pad comprises metal or organic materials.

4. The chip package fabricating kit of claim 1, further comprising:
a metal plate, disposed between the at least one screw cap and the PCB board at a second side that is opposite to the first side of said PCB board.

5. The chip package fabricating kit of claim 4, wherein the metal plate is configured to substantially contact with the PCB board at the second side of said PCB board, and configured to clamp the PCB board onto the BGA package with the aid of the metal cover.

6. The chip package fabricating kit of claim 1, the metal cover comprises stainless steel, alloy or other heat-resisting and stiff materials.

7. The chip package fabricating kit of claim 1, wherein the at least one leg of the metal cover is configured to form an enclosing edge that surrounds the BGA package.

8. The chip package fabricating kit of claim 1, wherein the BGA package comprises:
a chip;
a metal frame, configured to substantially surround the chip; and
a substrate, configured to load both the chip and the metal frame.

9. The chip package fabricating kit of claim 8, wherein the BGA package further comprises:
a plurality of solder balls, disposed between the substrate and the PCB board, and configured to stick the substrate to the PCB board upon soldering.

10. The chip package fabricating kit of claim 8, wherein the BGA package further comprises:
a plurality of solder pins, disposed between the substrate and the chip, and configured to attach the chip to the substrate by soldering.

11. The chip package fabricating kit of claim 8, wherein the BGA package further comprises:
an adhesive disposed between the metal frame and the substrate, and configured to attach the metal frame to the substrate.

12. A chip package fabricating method, comprising:
disposing at least one BGA package onto a PCB board;
disposing a metal cover that substantially contacts with a chip and a metal frame of the BGA package that surrounds the chip to encompass the BGA package;
pressing the metal cover against the BGA package such that a substrate of the BGA package substantially contacts with the PCB board, wherein the substrate substantially loads the chip and the metal frame;
screwing at least one screw respectively through each of at least one leg of the metal cover from top to bottom and through the PCB board;
capping at least one screw cap that respectively corresponds with the at least one screw to a tail of each the at least one screw for affixing the BGA package onto the PCB board; and
baking the BGA package.

13. The chip package fabricating method of claim 12, further comprising:
sputtering a thermal interface material (TIM) layer onto the BGA package.

14. The chip package fabricating method of claim 12, further comprising:
disposing a metal plate between the PCB board and the at least one screw cap.

15. The chip package fabricating method of claim 14, wherein capping the at least one screw cap comprises:
capping the at least one screw cap to the tail of each the at least one screw for clamping PCB board onto the BGA package.

16. The chip package fabricating method of claim 12, further comprising:
dynamically adjusting a degree that the at least one screw screws with the at least one screw cap, such that a concave space of the metal cover substantially clamps the BGA package.

17. The chip package fabricating method of claim 12, further comprising:
disposing at least one buffer pad that respectively corresponds to the at least one leg of the metal cover between the at least one leg of the metal cover and the PCB board.

18. The chip package fabricating method of claim 12, further comprising:
disposing a plurality of soldering pins between the chip and the substrate of the BGA package;
wherein baking the BGA package comprises soldering the plurality of soldering pins for affixing the chip onto the substrate.

19. The chip package fabricating method of claim 12, further comprising:
disposing a plurality of soldering balls between the substrate of the BGA package and the PCB board;
wherein baking the BGA package comprises soldering the plurality of soldering balls for affixing the substrate onto the PCB board.

20. The chip package fabricating method of claim 12, further comprising:
disposing an adhesive between the metal frame and the substrate for firmly attaching the metal frame to the substrate.
